(19) United States
(12) Patent Application Publication
(10) Pub. No.: US 2026/0253780 A1
(43) Pub. Date: Aug. 27, 2026

(54) METHODS AND APPARATUS TO MANUFACTURE A COUPLED INDUCTOR

(71) Applicant: Intel Corporation, Santa Clara, CA (US)

(72) Inventors: Xiaoguo Liang, Shanghai (CN); Ahmed Abou-Alfotouh, Dublin, CA (US); Alan Wu, Toronto (CA); Kaladhar Radhakrishnan, Chandler, AZ (US); Jonathan Douglas, Cave Creek, AZ (US); Wei Dai, Shanghai (CN)

(73) Assignee: Intel Corporation, Santa Clara, CA (US)

(21) Appl. No.: 18/992,513

(22) PCT Filed: Sep. 29, 2022
(86) PCT No.: PCT/CN2022/122564

§ 371 Date: Jan. 8, 2025

(51) Int. Cl. H01F 27/24; H01F 27/28; H01F 41/02; H01F 41/04

(52) U.S. Cl. CPC H01F 27/24; H01F 27/2823; H01F 41/0206; H01F 41/04

(57) ABSTRACT

Methods and apparatus to manufacture a coupled inductor are disclosed. An example coupled inductor includes a base of a magnetic core including a first channel and a second channel extending between first and second sides of the base, the first channel spaced apart from the second channel, a third channel of the base extending transverse to the first and second channels, a first conductive wire positioned in the base, a first portion of the first conductive wire positioned in the first channel, a second portion of the first conductive wire positioned in the second channel, a third portion of the first conductive wire positioned in the third channel, and a first portion of a second conductive wire positioned in the first channel, a second portion of the conductive wire positioned in the second channel, a third portion of the second conductive wire positioned in the third channel.

### FIELD OF THE DISCLOSURE

This disclosure relates generally to electronic circuits and, more particularly, to methods and apparatus to manufacture a coupled inductor.

### BACKGROUND

Many electrical circuit devices include substrates (e.g., integrated circuit (IC) package substrates, printed circuit boards (PCBs), etc.) with resistors, capacitors, inductors, or any other components for routing electrical signals. Inductive couplers may be used to magnetically convey electrical signals between different sections of an IC.

### BRIEF DESCRIPTION OF THE DRAWINGS

FIG. 1 illustrates an example integrated circuit (IC) package constructed in accordance with teachings disclosed herein.

FIG. 2 is a plan view of an example coupled inductor constructed in accordance with teachings disclosed herein.

FIG. 3 is a flowchart representative of example methods to produce the example coupled inductor of FIG. 2.

FIGS. 4-9 depict the example coupled inductor of FIG. 1 at various manufacturing stages corresponding to the example methods of FIG. 3.

FIG. 10 depicts another example coupled inductor constructed in accordance with teachings disclosed herein.

FIG. 11 depicts another example coupled inductor constructed in accordance with teachings disclosed herein.

FIG. 12 depicts yet another example coupled inductor constructed in accordance with teachings disclosed herein.

FIG. 13 is a cross-sectional side view of an IC device assembly that may include the example package of FIG. 1 constructed in accordance with teachings disclosed herein.

FIG. 14 is a block diagram of an example electrical device that may include the example package of FIG. 1 constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

Notwithstanding the foregoing, in the case of a semiconductor device, “above” is not with reference to Earth, but instead is with reference to a bulk region of a base semiconductor substrate (e.g., a semiconductor wafer) on which components of an integrated circuit are formed. Specifically, as used herein, a first component of an integrated circuit is “above” a second component when the first component is farther away from the bulk region of the semiconductor substrate than the second component.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, “connection references” (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly that might, for example, otherwise share a same name.

As used herein, “processor circuitry” is defined to include (i) one or more special purpose electrical circuits structured to perform specific operation(s) and including one or more semiconductor-based logic devices (e.g., electrical hardware implemented by one or more transistors), and/or (ii) one or more general purpose semiconductor-based electrical circuits programmable with instructions to perform specific operations and including one or more semiconductor-based logic devices (e.g., electrical hardware implemented by one or more transistors). Examples of processor circuitry include programmable microprocessors, Field Programmable Gate Arrays (FPGAs) that may instantiate instructions, Central Processor Units (CPUs), Graphics Processor Units (GPUs), Digital Signal Processors (DSPs), XPUs, or microcontrollers and integrated circuits such as Application Specific Integrated Circuits (ASICs). For example, an XPU may be implemented by a heterogeneous computing system including multiple types of processor circuitry (e.g., one or more FPGAs, one or more CPUs, one or more GPUs, one or more DSPs, etc., and/or a combination thereof) and application programming interface(s) (API(s)) that may assign computing task(s) to whichever one(s) of the multiple types of processor circuitry is/are best suited to execute the computing task(s).

### DETAILED DESCRIPTION

Integrated circuits (ICs) frequently include analog components that require a reference (e.g., stable, constant, etc.) voltage for operation. These reference voltages are preferably generated such that a substantially constant reference voltage is provided as an output, regardless of any changes that occur in the IC, such as fluctuations in the input voltage, temperature fluctuations, changes in the loading conditions, etc. Electronic circuits can utilize voltage regulators to maintain reference voltages.

In some examples, voltage regulators utilize coupled inductors for maintenance of the reference voltage. In coupled inductors, two wires are wrapped around a magnetic core. In particular, the two or more wires are wrapped in opposite directions. As current flows through the wires, a voltage is induced by the coupled current and energy is stored in the magnetic field. The efficiency of a coupled inductor, and thus the efficiency of a voltage regulator, depends on the magnetic core material properties as well as the physical arrangement of the wire windings and the core.

One approach to improve the transient performance of a voltage regulator in electronic circuits is to utilize inversely coupled inductors. Inversely coupled inductors reduce output decoupling due to improved transient response and can reduce inductor size based on magnetic integration and the cancellation of magnetic flux (e.g., the magnetic flux at side legs).

However, inversely coupled inductors can increase a length of a current flowpath (e.g., increase in the length of the power delivery) in the voltage regular layout. In some examples, increasing the length of a current flowpath can increase the resistivity of a circuit. For example, increasing the length of a current flowpath can cause excessive root-mean-square (RMS) loss in the electronic circuit.

Examples disclosed herein improve the efficiency of voltage regulators by reducing overall Rpath impedance. Examples disclosed herein increase voltage regulator power density by reducing output decoupling and inductor size. Further, examples disclosed herein utilize additional windings of the inductor to improve the efficiency of the voltage regulator.

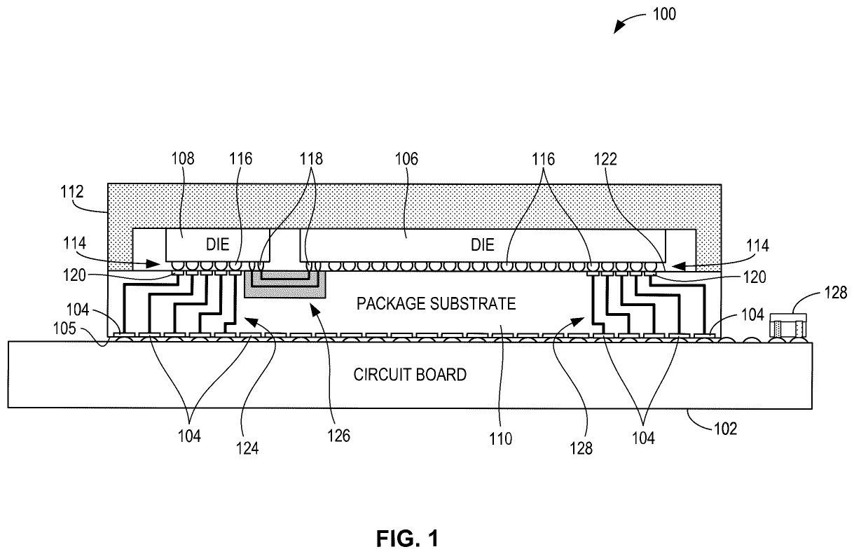

FIG. 1 illustrates an example IC package 100 constructed in accordance with teachings disclosed herein. In the illustrated example, the IC package 100 is electrically coupled to a circuit board 102 via an array of contact pads or lands 104 on a mounting surface (e.g., a bottom surface) 105. In some examples, the IC package 100 may include balls, pins, and/or pads, in addition to or instead of the contact pads 104, to enable the electrical coupling of the package 100 to the circuit board 102. In this example, the package 100 includes two semiconductor (e.g., silicon) dies 106, 108 (sometimes also referred to as chips or chiplets) that are mounted to a package substrate 110 and enclosed by a package lid or mold compound 112. While the example IC package 100 of FIG. 1 includes two dies 106, 108, in other examples, the package 100 may have only one die or more than two dies. The dies 106, 108 can provide any suitable type of functionality (e.g., data processing, memory storage, etc.).

As shown in the illustrated example, each of the dies 106, 108 is electrically and mechanically coupled to the substrate 110 via corresponding arrays of interconnects (e.g., balls, bumps, wire bonding, etc.) 114. The electrical connections between the dies 106, 108 and the substrate 110 (e.g., the interconnects 114) are sometimes referred to as first level interconnects. By contrast, the electrical connections between the IC package 100 and the circuit board 102 (e.g., the pads 104) are sometimes referred to as second level interconnects. In some examples, one or both of the dies 106, 108 may be stacked on top of one or more other dies and/or an interposer. In such examples, the dies 106, 108 are coupled to the underlying die and/or interposer through a first set of first level interconnects and the underlying die and/or interposer may be connected to the package substrate 110 via a separate set of first level interconnects associated with the underlying die and/or interposer. Thus, as used herein, first level interconnects refer to interconnects (e.g., balls, bumps, wire bonding, etc.) between a die and a package substrate or a die and an underlying die and/or interposer.

As shown in FIG. 1, the interconnects 114 of the first level interconnects include two different types of bumps corresponding to core bumps 116 and bridge bumps 118. As used herein, core bumps 116 refer to bumps of the dies 106, 108 through which electrical signals pass between the dies 106, 108 and components external to the IC package 100. More particularly, as shown in the illustrated example, when the dies 106, 108 are mounted to the package substrate 110, the core bumps 116 are physically connected and electrically coupled to contact pads 120 on an inner surface 122 of the substrate 110. The contact pads 120 on the inner surface 122 of the package substrate 110 are electrically coupled to the landing pads 104 on the bottom (external) surface 105 of the substrate 110 (e.g., a surface opposite the inner surface 122) via internal interconnects 124 within the substrate 110. As a result, there is a complete signal path between the interconnects 114 of the dies 106, 108 and the landing pads 104 mounted to the circuit board 102 that pass through the contact pads 120 and the interconnects 124 provided therebetween.

As used herein, bridge bumps 118 refer to bumps on the dies 106, 108 through which electrical signals pass between different ones of the dies 106, 108 within the package 100. Thus, as shown in the illustrated example, the bridge bumps 118 of the first die 106 are electrically coupled to the bridge bumps 118 of the second die 108 via an interconnect bridge 126 embedded in the package substrate 110. As represented in FIG. 1, core bumps 116 are typically larger than bridge bumps 118. In some examples, the interconnect bridge 126 and the associated bridge bumps 118 are omitted.

In the illustrated example of FIG. 1 and in accordance with teachings disclosed herein, the example circuit board 102 can include embedded devices, including both passive and active devices. Such devices may include, but are not limited to, capacitors, decoupling capacitors, resistors, inductors, fuses, diodes, transformers, sensors, electrostatic discharge (ESD) devices, and memory devices. In the example of FIG. 1, the example circuit board 102 includes an example coupled inductor 128. In particular, the example coupled inductor 128 is electrically coupled to the circuit board 102 via the contact pads 104. The example coupled inductor 128 can improve the electrical performance of the IC package 100 by reducing overall Rpath impedance, output decoupling capacitors and inductor size.

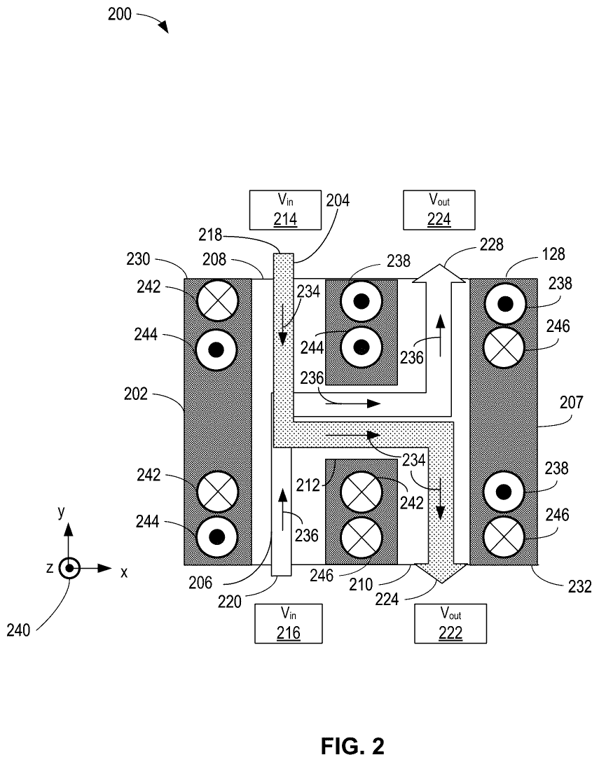

FIG. 2 is a schematic 200 of the example coupled inductor 128 that can be implemented in the IC package 100 of FIG. 1. In particular, the example schematic 200 illustrates the functioning (e.g., current flow, flux direction, electrical connections, etc.) of the coupled inductor 128. In the illustrated example of FIG. 2, the example coupled inductor includes a magnetic core 202 and conductive wires 204, 206. The magnetic core 202 includes a base 207 having channels 208, 210, 212. The example coupled inductor 128 may be electrically coupled to voltage supplies 214, 216. In particular, an end 218 of the conductive wire 204 is electrically coupled to the voltage supply 214 and an end 220 of the conductive wire 206 is electrically coupled to the voltage supply 216. In some examples, the voltage supplies 214, 216 are regulated (e.g. monitored, powered, etc.) by a voltage regulator module (VRM). Further, voltage sinks 222, 224 provide a terminal to receive current flow. As such, an end 224 of the conductive wire 204 is electrically coupled to the voltage sink 222 and an end 228 of the conductive wire is electrically coupled to the voltage sink 224. In this example, the voltage supply 214 and the voltage sink 224 are positioned on a first side 230 of the magnetic core 202 and the voltage supply 216 and the voltage sink 222 are positioned on a second side 232 of the magnetic core 202. Accordingly, the ends 218, 228 are adjacent to the first side 230 and the ends 220, 224 are adjacent to the second side 232.

In FIG. 2, the conductive wires 204, 206 are arranged (e.g., positioned, routed, etc.) within the channels 208, 210, 212. In this example, the channel 208 is spaced apart from the channel 210, and the channels 208, 210 are substantially (e.g., within 5%) parallel. The example channels 208, 201 are traversed (e.g., intersected) by the channel 212. As such, the example channel 212 couples (e.g., joins) the channel 208 and the channel 210. In some examples, the channels 208, 210, 212 can exhibit a generally curved shape. In this example, the channels 208, 210, 212 are approximately (e.g., within 5%) the same width. However, the example channels 208, 210, 212 can vary in length, width, etc.

The example conductive wire 204 is positioned in the channel 208, the channel 210, and the channel 212. In particular, a first portion of the conductive wire 204 is positioned in the channel 208, a second portion of the conductive wire 204 is positioned in the channel 212, and a third portion of the conductive wire 204 is positioned in the channel 210. Further, the example conductive wire 206 is positioned in the channel 208, the channel 212, and the channel 210. In particular, a first portion of the conductive wire 206 is positioned in the channel 208, a second portion of the conductive wire 206 is positioned in the channel 212, and a third portion of the conductive wire 206 is positioned in the channel 210. In the illustrated example of FIG. 2, the conductive wire 204 is positioned at a first depth of the magnetic core 202 and the conductive wire 206 is positioned at a second depth of the magnetic core 202, the second depth greater than the first depth.

In the example schematic 200 of the coupled inductor 128 of FIG. 2, current is to flow through the conductive wires 204, 206. In the example conductive wire 204, current is to flow in a direction along the channels 208, 212, 210 from one side 230 of the base 207 to the other side 232 of base 207, as generally indicated by arrows 234. In the example conductive wire 206, current is to flow in a direction along the channels 208, 212, 210 from one side 232 of the base 207 to the other side 230 of base 207, as generally indicated by arrows 236. Accordingly, current is to flow through the conductive wire 204 from the voltage supply 214 to the voltage sink 222.

Further, current is to flow through the conductive wire 206 from the voltage supply 216 to the voltage sink 224.

In this example, the conductive wires 204, 206 exhibit a generally straight shape and/or orientation. However, the conductive wires 204, 206 can exhibit a coiled shape. For example, the conductive wire 204 can exhibit a generally coiled shape in the clockwise direction and the conductive wire 206 can exhibit a generally coiled shape in the counterclockwise direction. When current flows through the example conductive wire 204, the current flow generates a first magnetic field that radially surrounds the conductive wire 204. Additionally, when current flows through the example conductive wire 206, the current flow generates a second magnetic field that radially surrounds the conducive wire 206. In the example coupled inductor 128, the magnetic 202 creates the path to allows the first magnetic field of the wire 204 to couple to the second magnetic field of the wire 206. As such, the example coupled inductor 128 generates a magnetic field, wherein the magnetic field includes the first magnetic field and the second magnetic field. As used herein, “magnetic flux” is a measurement of the direction and magnitude of a magnetic field. In the example of FIG. 2, the dot notations 238 indicate magnetic flux resulting from current flowing in the conductive wire 204 in a z direction 240 and the dot notations 242 indicate magnetic flux resulting from current flowing in the conductive wire 204 in the −z (e.g., negative z) direction 240. Further, the dot notations 244 indicate magnetic flux resulting from current flowing in the conductive wire 206 in the z direction 240 and the dot notations 246 indicate magnetic flux resulting from current flowing in the conductive wire 206 in the −z (e.g., negative z) direction 240.

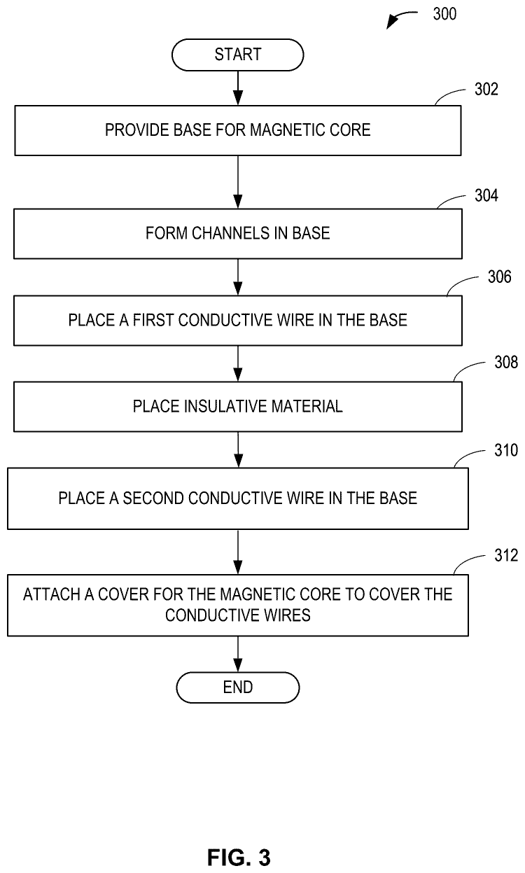

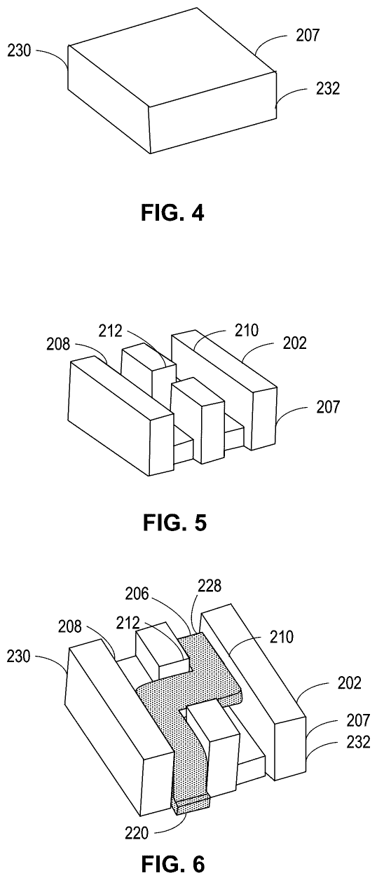

FIG. 3 is a flowchart representative of example methods to produce the example coupled inductor 128 of FIG. 1. FIGS. 4-9 represent the example coupled inductor 128 at various stages during the process described in FIG. 3.

Turning to FIG. 3, the example process 300 begins at block 302 at which the base 207 for the magnetic core 202 is provided. As shown in FIG. 4, the base 207 includes the first side 230 and the second side 232.

At block 304, the channels 208, 210, 212 are formed in the base 207, as shown in FIG. 5. In particular, the channel 208 extends through the base 207 alongside the channel 210. Further, the channel 212 extends from the channel 208 and the channel 210.

At block 306, the conductive wire 206 is placed (e.g., positioned) in the base 207, as shown in FIG. 6. In particular, the conductive wire 206 extends continuously through the channels 208, 212, 210 from the side 232 to the side 230. As shown in the example of FIG. 6, different portions of the conductive wire 206 are positioned in different ones of the channels 208, 212, 210. Additionally, the end 220 of the conductive wire 206 extends vertically along the side 232 of the base 207 and the end 228 of the conductive wire 206 extends vertically along the side 230 of the base 207.

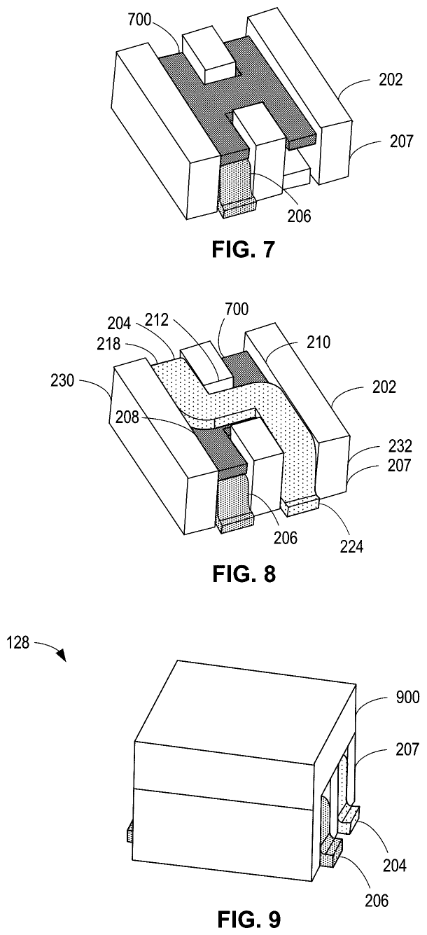

At block 308, an insulative material 700 is placed in the base 207, as shown in FIG. 7. In particular, the insulative material 700 is deposited on the conductive wire 206. In some examples, the insulative material 700 is mylar.

At block 310, the conductive wire 204 is placed in the base 207. In particular, the conductive wire 204 extends continuously through the channels 208, 212, 210 from the side 230 to the side 232, as shown in FIG. 8. Further, different portions of the conductive wire 204 are positioned in different ones of the channels 208, 212, 210. Additionally, the end 218 of the conductive wire 204 extends vertically along the side 230 of the base 207 and the end 224 of the conductive wire 204 extends vertically along the side 232 of the base 207.

As shown in the example of FIG. 8, the conductive wire 204 is deposited on the insulative material 700. As such, the insulative material 700 separates (e.g., electrically isolates) the conductive wire 204 and the conductive wire 206. Moreover, in the example of at least FIGS. 6, 7, and 8, the conductive wires 204, 206 and the insulative material 700 are offset from one another on vertical planes. In other words, the conductive wires 204, 206 and the insulative material 700 are positioned at different depths in the base 207. In particular, the conductive wire 204 is positioned at a first depth, the insulative material 700 is positioned at a second depth, and the conductive wire 206 is positioned at a third depth, wherein the second depth is greater than the first depth, and the third depth is greater than the first and the second depth.

At block 312, a cover 900 for the magnetic core 202 is attached to cover (e.g., enclose, at least partially enclose, at least partially cover, etc.) the conductive wires 204, 206, as shown in FIG. 9. The cover 900 can be same magnetic material or different magnetic material used for base 207. In some examples, the coupled inductor 128 can have air gaps between the cover 900 and base 207 for insulating purposes and/or to prevent shorts between the conductive wires 204, 206. Then, the process of FIG. 3 ends.

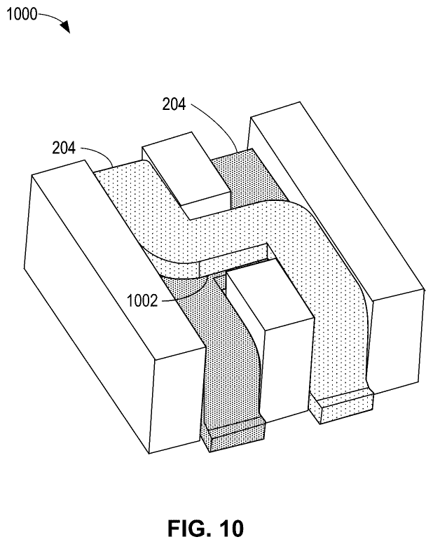

FIG. 10 illustrates an example coupled inductor 1000. The example coupled inductor 1000 of FIG. 10 is similar to the example coupled inductor 200 of FIG. 2, but, instead includes a mylar insulator 1002. In the example of FIG. 10, the mylar insulator 1002 separates the conductive wire 204 and the conductive wire 206.

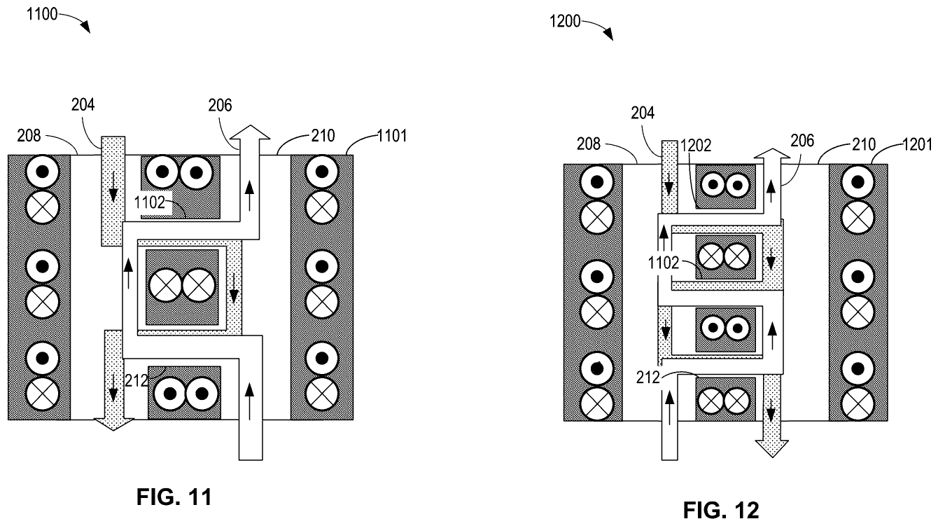

FIG. 11 is a schematic 1100 of an example coupled inductor 1101 that can be implemented in the IC package 100 of FIG. 1. In particular, the example schematic 1100 illustrates the functioning (e.g., current flow, flux direction, electrical connections, etc.) of the coupled inductor 1101. The example coupled inductor 1101 of FIG. 11 is similar to the example coupled inductor 128 of FIG. 2, but, instead includes an additional example channel 1102. As shown in the example of FIG. 11, the channel 1102 extends transverse to the channels 208, 210, thereby coupling the channel 208 to the channel 210. Further, the channel 1102 is spaced apart from the channel 212. In FIG. 11, a portion of the conductive wire 204 and a portion of the conductive wire 206 are positioned in the channel 1102.

FIG. 12 a schematic 1200 of an example coupled inductor 1201 that can be implemented in the IC package 100 of FIG. 1. In particular, the example schematic 1200 illustrates the functioning (e.g., current flow, flux direction, electrical connections, etc.) of the coupled inductor 1201. The example coupled inductor 1201 of FIG. 12 is similar to the example coupled inductor 1100 of FIG. 11, but, instead includes an additional example channel 1202. As shown in the example of FIG. 12, the channel 1202 extends transverse to the channels 208, 210, thereby coupling the channel 208 to the channel 210. Further, the channel 1202 is spaced apart from the channel 212 and the channel 1102. In FIG. 12, a portion of the conductive wire 204 and a portion of the conductive wire 206 are positioned in the channel 1202.

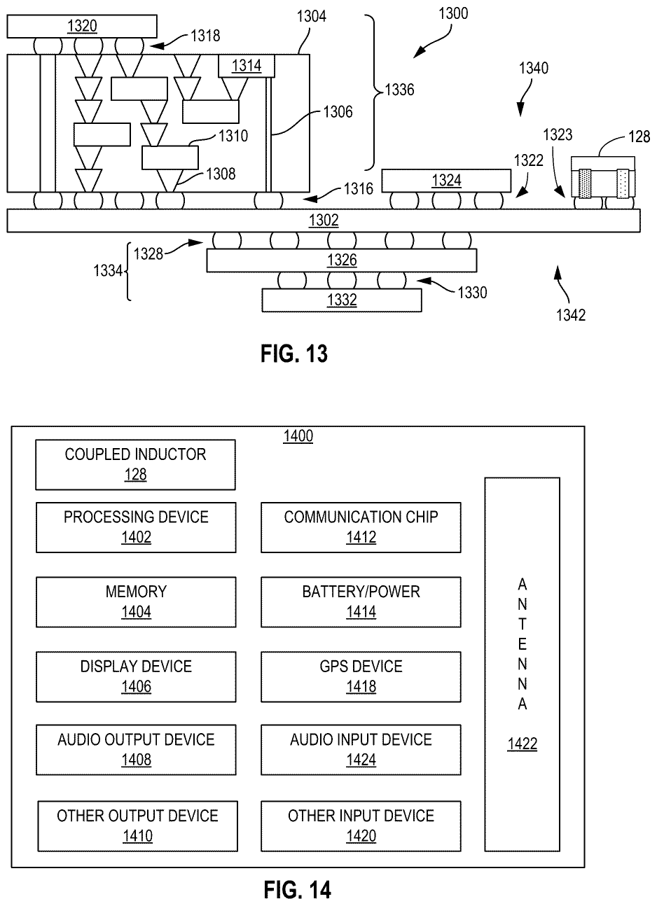

FIG. 13 is a cross-sectional side view of an IC device assembly 1300 that may include the IC package 100 disclosed herein. In some examples, the IC device assembly corresponds to the IC package 100. The IC device assembly 1300 includes a number of components disposed on a circuit board 1302 (which may be, for example, a motherboard). The IC device assembly 1300 includes components disposed on a first face 1340 of the circuit board 1302 and an opposing second face 1342 of the circuit board 1302; generally, components may be disposed on one or both faces 1340 and 1342. Any of the IC packages discussed below with reference to the IC device assembly 1300 may take the form of the example IC package 100 of FIG. 1.

In some examples, the circuit board 1302 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1302. In other examples, the circuit board 1302 may be a non-PCB substrate. In some examples, the circuit board 1302 may be, for example, the circuit board 102 of FIG. 1.

The IC device assembly 1300 illustrated in FIG. 13 includes a package-on-interposer structure 1336 coupled to the first face 1340 of the circuit board 1302 by coupling components 1316. The coupling components 1316 may electrically and mechanically couple the package-on-interposer structure 1336 to the circuit board 1302, and may include solder balls (as shown in FIG. 13), male and female portions of a socket, an adhesive, an underfill material, and/or any other suitable electrical and/or mechanical coupling structure.

The package-on-interposer structure 1336 may include an IC package 1320 coupled to an interposer 1304 by coupling components 1318. The coupling components 1318 may take any suitable form for the application, such as the forms discussed above with reference to the coupling components 1316. Although a single IC package 1320 is shown in FIG. 13, multiple IC packages may be coupled to the interposer 1304; indeed, additional interposers may be coupled to the interposer 1304. The interposer 1304 may provide an intervening substrate used to bridge the circuit board 1302 and the IC package 1320. The IC package 1320 may be or include, for example, a die, an IC device, or any other suitable component. Generally, the interposer 1304 may spread a connection to a wider pitch or reroute a connection to a different connection. For example, the interposer 1304 may couple the IC package 1320 (e.g., a die) to a set of BGA conductive contacts of the coupling components 1316 for coupling to the circuit board 1302. In the example illustrated in FIG. 13, the IC package 1320 and the circuit board 1302 are attached to opposing sides of the interposer 1304; in other examples, the IC package 1320 and the circuit board 1302 may be attached to a same side of the interposer 1304. In some examples, three or more components may be interconnected by way of the interposer 1304.

In some examples, the interposer 1304 may be formed as a PCB, including multiple metal layers separated from one another by layers of dielectric material and interconnected by electrically conductive vias. In some examples, the interposer 1304 may be formed of an epoxy resin, a fiberglass-reinforced epoxy resin, an epoxy resin with inorganic fillers, a ceramic material, or a polymer material such as polyimide. In some examples, the interposer 1304 may be formed of alternate rigid or flexible materials that may include the same materials described above for use in a semiconductor substrate, such as silicon, germanium, and other group III-V and group IV materials. The interposer 1304 may include metal interconnects 1308 and vias 1310, including but not limited to through-silicon vias (TSVs) 1306. The interposer 1304 may further include embedded devices 1314, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1304. The package-on-interposer structure 1336 may take the form of any of the package-on-interposer structures known in the art.

The IC device assembly 1300 may include an IC package 1318 coupled to the first face 1340 of the circuit board 1302 by coupling components 1322. The coupling components 1322 may take the form of any of the examples discussed above with reference to the coupling components 1316, and the IC package 1324 may take the form of any of the examples discussed above with reference to the IC package 1320. The example IC device assembly 1300 includes the example coupled inductor 128. However, the example IC device assembly 1330 can include any of the coupled inductors 1000, 1101, 1201. In this example, the example coupled inductor 128 is electrically coupled to the circuit board 1302 via the coupling components 1323.

The IC device assembly 1300 illustrated in FIG. 13 includes a package-on-package structure 1334 coupled to the second face 1342 of the circuit board 1302 by coupling components 1328. The package-on-package structure 1334 may include a first IC package 1326 and a second IC package 1332 coupled together by coupling components 1330 such that the first IC package 1326 is disposed between the circuit board 1302 and the second IC package 1332. The coupling components 1328, 1330 may take the form of any of the examples of the coupling components 1316 discussed above, and the IC packages 1326, 1332 may take the form of any of the examples of the IC package 1320 discussed above. The package-on-package structure 1334 may be configured in accordance with any of the package-on-package structures known in the art.

FIG. 14 is a block diagram of an example electrical device 1400 that may include one or more of the example IC packages 100 of FIG. 1. For example, any suitable ones of the components of the electrical device 1400 may include one or more of the device assemblies 1300, coupled inductors, IC devices, or dies disclosed herein, and may be arranged in the example IC package 100. In particular, the example electrical device 1400 includes the example coupled inductor 128. However, the example electrical device 1400 can include any of the coupled inductors 128, 1000, 1101, 1201. A number of components are illustrated in FIG. 14 as included in the electrical device 1400, but any one or more of these components may be omitted or duplicated, as suitable for the application. In some examples, some or all of the components included in the electrical device 1400 may be attached to one or more motherboards. In some examples, some or all of these components are fabricated onto a single system-on-a-chip (SoC) die.

Additionally, in various examples, the electrical device 1400 may not include one or more of the components illustrated in FIG. 14, but the electrical device 1400 may include interface circuitry for coupling to the one or more components. For example, the electrical device 1400 may not include a display 1406, but may include display interface circuitry (e.g., a connector and driver circuitry) to which a display 1406 may be coupled. In another set of examples, the electrical device 1400 may not include an audio input device 1424 (e.g., microphone) or an audio output device 1408 (e.g., a speaker, headset, earbuds, etc.), but may include audio input or output device interface circuitry (e.g., connectors and supporting circuitry) to which an audio input device 1424 or audio output device 1408 may be coupled.

The electrical device 1400 may include processor circuitry 1402 (e.g., one or more processing devices). As used herein, the term “processing device” or “processor” may refer to any device or portion of a device that processes electronic data from registers and/or memory to transform that electronic data into other electronic data that may be stored in registers and/or memory. The processor circuitry 1402 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processor circuitry. The electrical device 1400 may include a memory 1404, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 1404 may include memory that shares a die with the processor circuitry 1402. This memory may be used as cache memory and may include embedded dynamic random access memory (eDRAM) or spin transfer torque magnetic random access memory (STT-MRAM).

In some examples, the electrical device 1400 may include a communication chip 1412 (e.g., one or more communication chips). For example, the communication chip 1412 may be configured for managing wireless communications for the transfer of data to and from the electrical device 1400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 1412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-1605 Amendment), Long-Term Evolution (LTE) project along with any amendments, updates, and/or revisions (e.g., advanced LTE project, ultra mobile broadband (UMB) project (also referred to as “3GPP 2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1412 may operate in accordance with other wireless protocols in other examples. The electrical device 1400 may include an antenna 1422 to facilitate wireless communications and/or to receive other wireless communications (such as AM or FM radio transmissions).

In some examples, the communication chip 1412 may manage wired communications, such as electrical, optical, or any other suitable communication protocols (e.g., the Ethernet). As noted above, the communication chip 1412 may include multiple communication chips. For instance, a first communication chip 1412 may be dedicated to shorter-range wireless communications such as Wi-Fi or Bluetooth, and a second communication chip 1412 may be dedicated to longer-range wireless communications such as global positioning system (GPS), EDGE, GPRS, CDMA, WiMAX, LTE, EV-DO, or others. In some examples, a first communication chip 1412 may be dedicated to wireless communications, and a second communication chip 1412 may be dedicated to wired communications.

The electrical device 1400 may include battery/power circuitry 1414. The battery/power circuitry 1414 may include one or more energy storage devices (e.g., batteries or capacitors) and/or circuitry for coupling components of the electrical device 1400 to an energy source separate from the electrical device 1400 (e.g., AC line power).

The electrical device 1400 may include a display 1406 (or corresponding interface circuitry, as discussed above). The display 1406 may include any visual indicators, such as a heads-up display, a computer monitor, a projector, a touchscreen display, a liquid crystal display (LCD), a light-emitting diode display, or a flat panel display.

The electrical device 1400 may include an audio output device 1408 (or corresponding interface circuitry, as discussed above). The audio output device 1408 may include any device that generates an audible indicator, such as speakers, headsets, or earbuds.

The electrical device 1400 may include an audio input device 1424 (or corresponding interface circuitry, as discussed above). The audio input device 1424 may include any device that generates a signal representative of a sound, such as microphones, microphone arrays, or digital instruments (e.g., instruments having a musical instrument digital interface (MIDI) output).

The electrical device 1400 may include GPS circuitry 1418. The GPS circuitry 1418 may be in communication with a satellite-based system and may receive a location of the electrical device 1400, as known in the art.

The electrical device 1400 may include any other output device 1410 (or corresponding interface circuitry, as discussed above). Examples of the other output device 1410 may include an audio codec, a video codec, a printer, a wired or wireless transmitter for providing information to other devices, or an additional storage device.

The electrical device 1400 may include any other input device 1420 (or corresponding interface circuitry, as discussed above). Examples of the other input device 1420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader. The electrical device 1400 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 1400 may be any other electronic device that processes data.

From the foregoing, it will be appreciated that example systems, methods, apparatus, and articles of manufacture have been disclosed that improve the efficiency of voltage regulators by reducing overall Rpath impedance. Examples disclosed herein increase voltage regulator power density by reducing output decoupling and inductor size. Further, examples disclosed herein utilized additional windings of the inductor to improve the efficiency of the voltage regulator.

Example 1 includes a coupled inductor comprising a base of a magnetic core including a first channel and a second channel extending between first and second sides of the base, the first channel spaced apart from the second channel, a third channel of the base extending transverse to the first and second channels, the third channel coupling the first channel and the second channel, a first conductive wire positioned in the base, a first portion of the first conductive wire positioned in the first channel, a second portion of the first conductive wire positioned in the second channel, a third portion of the first conductive wire positioned in the third channel, and a second conductive wire positioned in the base, a first portion of the second conductive wire positioned in the first channel, a second portion of the second conductive wire positioned in the second channel, a third portion of the second conductive wire positioned in the third channel.

Example 2 includes the coupled inductor of example 1, wherein current is to flow through the first conductive wire in a first direction along the third channel and current is to flow through the second conductive wire in the first direction along the third channel.

Example 3 includes the coupled inductor of any one of examples 1 or 2, wherein a first end of the first conductive wire is electrically coupled to a first voltage supply and a first end of the second conductive wire is electrically coupled to a second voltage supply, the first end of the first conductive wire adjacent the first side of the base, the first end of the second conductive wire adjacent the second side of the base.

Example 4 includes the coupled inductor of any one of examples 1-3, further including a cover of the magnetic core to cover the first conductive wire and the second conductive wire.

Example 5 includes the coupled inductor of any one of examples 1-4, wherein the first channel and the second channel are substantially parallel.

Example 6 includes the coupled inductor of any one of examples 1-5, wherein the first channel, the second channel, and the third channel are approximately the same width.

Example 7 includes the coupled inductor of any one of examples 1-6, wherein the first conductive wire is positioned at a first depth of the base and the second conductive wire is positioned at a second depth of the base, the first depth different from the second depth.

Example 8 includes the coupled inductor of any one of examples 1-7, wherein a first end of the first conductive wire is adjacent to the first side and a second end of the first conductive wire is adjacent to the second side, the first end positioned in the first channel and the second end positioned in the second channel.

Example 9 includes the coupled inductor of example 8, wherein the first end extends vertically along the first side of the base and the second end extends vertically along the second side of the base.

Example 10 includes the coupled inductor of any one of examples 1-7, wherein a first end of the second conductive wire is adjacent to the second side and a second end of the second conductive wire is adjacent to the first side, the first end positioned in the first channel and the second end positioned in the second channel.

Example 11 includes the coupled inductor of example 10, wherein the first end extends vertically along the second side of the base and the second end extends vertically along the first side of the base.

Example 12 includes the coupled inductor of any one of examples 1-11, further including an insulative material separating the first conductive wire from the second conductive wire.

Example 13 includes the coupled inductor of example 12, wherein the insulative material is mylar.

Example 14 includes the coupled inductor of any one of examples 1-13, further including a fourth channel extending transverse to the first and second channels, the fourth channel spaced apart from the third channel, the fourth channel coupling the first channel and the second channel.

Example 15 includes the coupled inductor of example 14, wherein a fourth portion of the first conductive wire and a fourth portion of the second conductive wire are positioned in the fourth channel.

Example 16 includes an apparatus including a base of a magnetic core defining a first channel, a second channel, and a third channel, the first channel intersecting both the second channel and the third channel, a first conductive wire extending through the first channel and first portions of the second channel, and a second conductive wire extending through the first channel and second portions of the second channel, the second portions different than the first portions.

Example 17 includes the apparatus of example 16, wherein current is to flow through the first conductive wire in a first direction in the second channel and current is to flow through the second conductive wire in a second direction in the second channel, the first direction different from the second direction.

Example 18 includes the apparatus of any one of examples 16 or 17, further including a first voltage supply positioned at a first side of the core and a second voltage supply positioned at a second side of the core, a first end of the first conductive wire electrically coupled to the first voltage supply and a first end of the second conductive wire electrically coupled to the second voltage supply.

Example 19 includes the apparatus of any one of examples 16-18, further including a cover of the magnetic core to at least partially enclose the first conductive wire and the second conductive wire.

Example 20 includes the apparatus of any one of examples 16-19, wherein the second channel and the third channel are substantially parallel.

Example 21 includes the apparatus of any one of examples 16-20, wherein the first channel, the second channel, and the third channel are approximately the same width.

Example 22 includes the apparatus of any one of examples 16-21, wherein the first conductive wire is vertically offset from the second conductive wire.

Example 23 includes the apparatus of any one of examples 16-22, wherein the first portions and the second portions extend in opposing directions.

Example 24 includes the apparatus of any one of examples 16-23, wherein a first end of the first conductive wire extends vertically along a first side of the base and at least one of the first portions extends vertically along a second side of the base.

Example 25 includes the apparatus of any one of examples 16-23, wherein a first end of the second conductive wire extends vertically along a second side of the base and at least one of the second portions extends vertically along a first side of the base.

Example 26 includes the apparatus of any one of examples 16-25, further including an insulative material positioned between the first conductive wire and the second conductive wire.

Example 27 includes the apparatus of example 26, wherein the insulative material is mylar.

Example 28 includes the apparatus of any one of examples 16-27, further including a fourth channel intersecting both the second channel and the third channel, the fourth channel spaced apart from the first channel, the fourth channel coupling the second channel and the third channel.

Example 29 includes the apparatus of example 28, wherein the first conductive wire extends through the first channel, the fourth channel, and first portions of the third channel and the second conductive wire extends through the first channel, the fourth channel, and second portions of the third channel, the second portions different than the first portions.

Example 30 includes a method of manufacturing a voltage regulator for use in an integrated circuit, the method comprising providing a base for a magnetic core, the base including a plurality of channels, a first one of the channels extending through the base alongside a second one of the channels, a third one of the channels extending from the first channel and the second channel, placing a first conductive wire to extend continuously through the channels from a first side of the base to a second side of the base, different portions of the first conductive wire positioned in different ones of the first, second, and third channels, and placing a second conductive wire to extend continuously through the channels from the second side of the base to the first side of the base, different portions of the second conductive wire positioned in different ones of the first, second, and third channels.

Example 31 includes the method of example 30, further including attaching a cover for the magnetic core to the base to enclose the first and second conductive wires within the magnetic core.

Example 32 includes the method of any one of examples 30 or 31, further including placing an insulative material to electrically isolate the first conductive wire from the second conductive wire.

The following claims are hereby incorporated into this Detailed Description by this reference. Although certain example systems, methods, apparatus, and articles of manufacture have been disclosed herein, the scope of coverage of this patent is not limited thereto. On the contrary, this patent covers all systems, methods, apparatus, and articles of manufacture fairly falling within the scope of the claims of this patent.

1. A coupled inductor comprising:
a base of a magnetic core including a first channel and a second channel extending between first and second sides of the base, the first channel spaced apart from the second channel, a third channel of the base extending transverse to the first and second channels, the third channel coupling the first channel and the second channel;
a first conductive wire positioned in the base, a first portion of the first conductive wire positioned in the first channel, a second portion of the first conductive wire positioned in the second channel, a third portion of the first conductive wire positioned in the third channel; and
a second conductive wire positioned in the base, a first portion of the second conductive wire positioned in the first channel, a second portion of the second conductive wire positioned in the second channel, a third portion of the second conductive wire positioned in the third channel.

2. The coupled inductor of claim 1, wherein current is to flow through the first conductive wire in a first direction along the third channel and current is to flow through the second conductive wire in the first direction along the third channel.

3. The coupled inductor of claim 1, wherein a first end of the first conductive wire is electrically coupled to a first voltage supply and a first end of the second conductive wire is electrically coupled to a second voltage supply, the first end of the first conductive wire adjacent the first side of the base, the first end of the second conductive wire adjacent the second side of the base.

4. The coupled inductor of claim 1, further including a cover of the magnetic core to cover the first conductive wire and the second conductive wire.

5. The coupled inductor of claim 1, wherein the first channel and the second channel are substantially parallel.

6. The coupled inductor of claim 1, wherein the first channel, the second channel, and the third channel are approximately the same width.

7. The coupled inductor of claim 1, wherein the first conductive wire is positioned at a first depth of the base and the second conductive wire is positioned at a second depth of the base, the first depth different from the second depth.

8. The coupled inductor of claim 1, wherein a first end of the first conductive wire is adjacent to the first side and a second end of the first conductive wire is adjacent to the second side, the first end positioned in the first channel and the second end positioned in the second channel.

9. The coupled inductor of claim 8, wherein the first end extends vertically along the first side of the base and the second end extends vertically along the second side of the base.

10-11. (canceled)

12. The coupled inductor of claim 1, further including an insulative material separating the first conductive wire from the second conductive wire.

13. The coupled inductor of claim 12, wherein the insulative material is mylar.

14. The coupled inductor of claim 1, further including a fourth channel extending transverse to the first and second channels, the fourth channel spaced apart from the third channel, the fourth channel coupling the first channel and the second channel.

15. The coupled inductor of claim 14, wherein a fourth portion of the first conductive wire and a fourth portion of the second conductive wire are positioned in the fourth channel.

16. An apparatus including:
a base of a magnetic core defining a first channel, a second channel, and a third channel, the first channel intersecting both the second channel and the third channel;
a first conductive wire extending through the first channel and first portions of the second channel; and
a second conductive wire extending through the first channel and second portions of the second channel, the second portions different than the first portions.

17. The apparatus of claim 16, wherein current is to flow through the first conductive wire in a first direction in the second channel and current is to flow through the second conductive wire in a second direction in the second channel, the first direction different from the second direction.

18. The apparatus of claim 16, further including a first voltage supply positioned at a first side of the core and a second voltage supply positioned at a second side of the core, a first end of the first conductive wire electrically coupled to the first voltage supply and a first end of the second conductive wire electrically coupled to the second voltage supply.

19. (canceled)

20. The apparatus of claim 16, wherein a first end of the first conductive wire extends vertically along a first side of the base and at least one of the first portions extends vertically along a second side of the base.

21. The apparatus of-any claim 16, further including a fourth channel intersecting both the second channel and the third channel, the fourth channel spaced apart from the first channel, the fourth channel coupling the second channel and the third channel.

22. (canceled)

23. A method of manufacturing a voltage regulator for use in an integrated circuit, the method comprising:
providing a base for a magnetic core, the base including a plurality of channels, a first one of the channels extending through the base alongside a second one of the channels, a third one of the channels extending from the first channel and the second channel;
placing a first conductive wire to extend continuously through the channels from a first side of the base to a second side of the base, different portions of the first conductive wire positioned in different ones of the first, second, and third channels; and
placing a second conductive wire to extend continuously through the channels from the second side of the base to the first side of the base, different portions of the second conductive wire positioned in different ones of the first, second, and third channels.

24. The method of claim 23, further including attaching a cover for the magnetic core to the base to enclose the first and second conductive wires within the magnetic core.

25. (canceled)
